(19) United States
(12) Patent Application Publication
(10) Pub. No.: US 2011/0254119 A1
(43) Pub. Date: Oct. 20, 2011

(54) Semiconductor Device and Method of Manufacturing the Same

(75) Inventor: Ji H. Seo, Bucheon-si (KR)

(73) Assignee: HYNIX SEMICONDUCTOR INC., Icheon-si (KR)

(21) Appl. No.: 13/116,880

(22) Filed: May 26, 2011

Related U.S. Application Data
(63) Continuation-in-part of application No. 12/495,240, filed on Jun. 30, 2009.

(30) Foreign Application Priority Data
Sep. 22, 2008 (KR) 10-2008-0092777
Apr. 10, 2009 (KR) 10-2009-0031320

(51) Int. Cl. H01L 21/336; H01L 27/04

(52) U.S. Cl. 257/499; 438/301; 438/296; 257/E21.409; 257/E27.01

(57) ABSTRACT

A method of manufacturing semiconductor devices includes forming a tunnel insulating layer, a conductive layer for a floating gate, and a hard mask layer on a semiconductor substrate, forming a first trench in the semiconductor substrate by partially etching the hard mask layer, the conductive layer for the floating gate, the tunnel insulating layer, and the semiconductor substrate, forming a first ion implantation region having a first impurity concentration into the semiconductor substrate of inner walls of the first trench by performing a first ion implantation process, forming a second trench extending from the first trench by etching the semiconductor substrate of a bottom of the first trench, and forming a second ion implantation region having a second impurity concentration lower than the first impurity concentration into the semiconductor substrate of inner walls of the second trench by performing a second ion implantation process, wherein a depth of the first trench is shallower than that of a junction region.

### CROSS-REFERENCE TO RELATED APPLICATION

This application is a continuation-in-part of U.S. patent application Ser. No. 12/495,240 filed on Jun. 30, 2009, which claims priority from Korean patent application number 10-2008-0092777 filed on 22 Sep., 2008, and Korean patent application number 10-2009-0031320 filed on 10 Apr., 2009, the contents of which are incorporated herein by reference in its entirety.

### BACKGROUND

The present invention relates to a semiconductor device and a method of manufacturing the same, and more particularly, to a semiconductor device capable of improving cycling characteristics and a method of manufacturing the same by maintaining boron concentration of the edge of the active region.

In general, in order to separate semiconductor devices, a semiconductor substrate is defined into an active region and a field region, word lines are formed in the active region, and isolation structures for isolating devices are formed in the field region.

In order to form the isolation structures of the semiconductor devices, trenches each having a shallow trench isolation (STI) structure are formed. A method of separating the devices by forming the trenches each having the STI structure is briefly described below. A trench is formed by etching a silicon substrate in the field region to a depth of about 3500 Å, and a high-density plasma (HDP) oxide layer is deposited thereon. Next, a chemical mechanical polishing (CMP) process is performed, thereby realizing separation between the devices.

In this case, before the isolation structures are formed, ion implantation for controlling the threshold voltage is performed on the semiconductor substrate using an ion implantation process. A phenomenon in which ions implanted during the ion implantation for controlling the threshold voltage diffuse into the sidewall oxide layer occurs because of the oxidization process. Accordingly, since the ions implanted in order to control the threshold voltage diffuse into the sidewall oxide layer, the active region has an irregular ion concentration distribution. Consequently, the irregular ion concentration distribution generates a hump phenomenon and causes to increase the leakage current leakage.

### BRIEF SUMMARY

A method of manufacturing semiconductor devices according to an aspect of the present invention comprises: forming a tunnel insulating layer, a conductive layer for a floating gate, and a hard mask layer on a semiconductor substrate; forming a first trench in the semiconductor substrate by partially etching the hard mask layer, the conductive layer for the floating gate, the tunnel insulating layer, and the semiconductor substrate; forming a first ion implantation region having a first impurity concentration into the semiconductor substrate of inner walls of the first trench by performing a first ion implantation process; forming a second trench extending from the first trench by etching the semiconductor substrate of a bottom of the first trench; and forming a second ion implantation region having a second impurity concentration lower than the first impurity concentration into the semiconductor substrate of inner walls of the second trench by performing a second ion implantation process, wherein a depth of the first trench is shallower than that of a junction region.

A method of manufacturing semiconductor devices according to another aspect of the present invention comprises: forming a tunnel insulating layer and a conductive layer for a floating gate over a semiconductor substrate; forming a first trench in the semiconductor substrate by partially etching the conductive layer for the floating gate, the tunnel insulating layer and the semiconductor substrate; forming a first ion implantation region in the semiconductor substrate of inner walls of the first trench by performing a first ion implantation process; forming a second trench extending from the first trench by etching the semiconductor substrate of a bottom of the first trench; forming a second ion implantation region in the semiconductor substrate of inner walls of the second trench by performing a second ion implantation process; forming an isolation structure by filling the first and the second trench with an insulating layer; exposing an active region of the semiconductor substrate by etching the conductive layer for the floating gate and the tunnel insulating layer in a direction of a word line; and forming a junction region in the semiconductor substrate of the exposed active region by performing a third ion implantation process, wherein a depth of the first trench is shallower than the junction region.

A semiconductor devices according to an aspect of the present invention comprises an isolation structure having a first and a second trench formed in a semiconductor substrate; a first ion implantation region formed in the semiconductor substrate of inner walls of the first trench having a first impurity concentration; and a second ion implantation region formed in the semiconductor substrate of inner walls of the second trench having a second impurity concentration which is lower than the first impurity concentration, wherein a depth of the first trench is shallower than that of a junction region.

### BRIEF DESCRIPTION OF THE DRAWINGS

FIGS. 1 to 6 are sectional views showing a method of forming the isolation structures of a semiconductor device according to an embodiment of this disclosure; and

FIG. 7 is a diagram showing the ion implantation directions of an ion implantation process during the ion implantation process of FIG. 6.

### DESCRIPTION OF SPECIFIC EMBODIMENT

Hereinafter, the disclosed embodiment is described in detail in connection with an embodiment with reference to the accompanying drawings. The figures are provided to allow those having ordinary skill in the art to understand the scope of the disclosed embodiment.

FIGS. 1 to 6 are sectional views showing a method of forming the isolation structures of a semiconductor device according to an embodiment of the disclosure.

Referring to FIG. 1, a tunnel insulating layer 101, a conductive layer for a floating gate 102, a buffer oxide layer 103, a nitride layer for a hard mask 104, an oxide layer for a hard mask 105, and a silicon oxynitride layer for a hard mask 106 are sequentially formed over a semiconductor substrate 100. In the meantime, a hard mask can be formed by single-layer structure using the nitride layer 104, the oxide layer 105 or the silicon oxynitride layer 106.

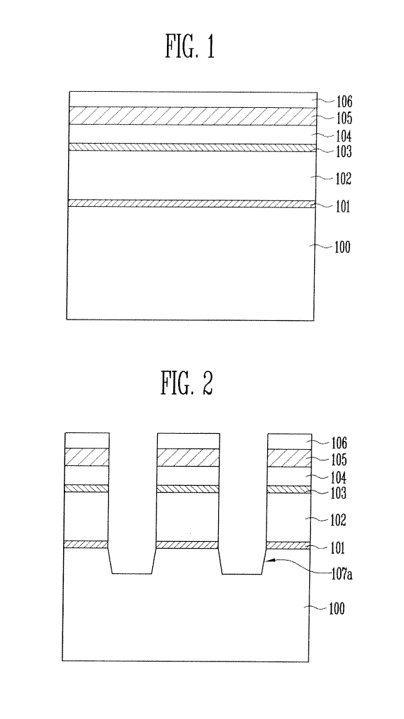

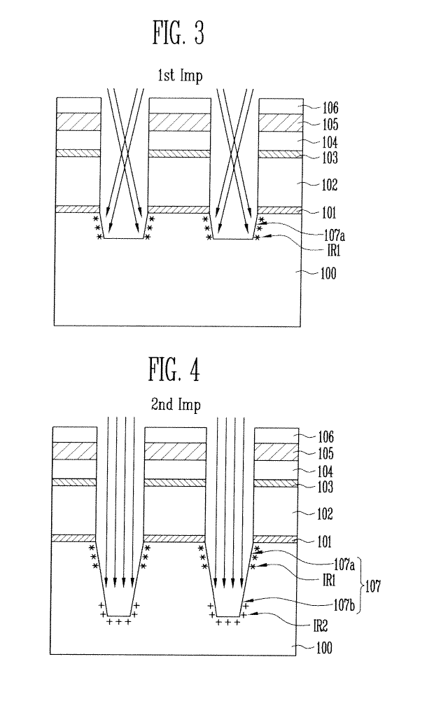

Referring to FIG. 2, the silicon oxynitride layer for a hard mask 106, the oxide layer for a hard mask 105, the nitride layer for a hard mask 104, the buffer oxide layer 103, the conductive layer for the floating gate 102, and the tunnel insulating layer 101 are partially etched using an etch process, thereby exposing specific regions of the semiconductor substrate 100. First trenches 107a are formed by etching the exposed regions of the semiconductor substrate 100. It is preferable to form the first trenches 107a that have a shallower depth than a junction region formed in the active region of the semiconductor substrate 100, the depth being measured from the surface of the semiconductor substrate 100. For example, if the junction region has a depth of 400 Å or more, it is preferable that the first trenches 107a have a depth of 400 Å or less when the depth is measured from the surface of the semiconductor substrate 100.

Referring to FIG. 3, a first ion implantation regions IR1 are formed by implanting ions into the semiconductor substrate 100 of inner wall of the first trenches 107a through a first shallow trench isolation (STI) ion implantation process. The first STI ion implantation process preferably is performed using boron or BF₂. The first STI ion implantation process preferably is performed at an implantation angle of 1° to 90° with respect to the semiconductor substrate and at a rotation angle of 1° to 45°. The first STI ion implantation process preferably is performed using an impurity concentration of 0.1E11 atoms/cm² to 1.0E13 atoms/cm². The STI ion implantation process preferably is performed with energy of 1K to 30K. Accordingly, an STI ion implantation concentration at each of the edge portions of the active region is increased, so Fowler-Nordheim (FN)-tunneling flux occurring at the edge portion of the active region during the program and erase operations of the device can be reduced. Consequently, a cycling characteristic of the device can be improved. Further, the edge and central portions of a junction region to be formed later can be formed uniformly within the active region.

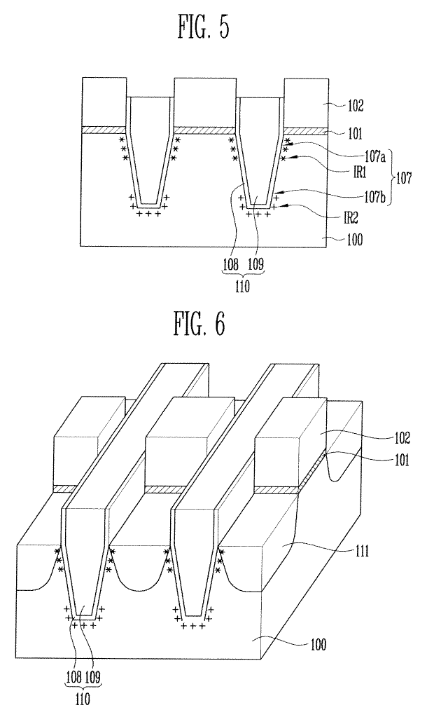

Referring to FIG. 4, the second trenches 107b extending from the first trenches 107a are formed by etching the semiconductor substrate 100 of a bottom of the first trenches 107a. Therefore isolation trench 107 is formed comprising the first trenches 107a and the second trenches 107b. Second ion implantation regions IR2 are formed in the semiconductor substrate 100 of the inner wall of the second trenches 107b and in the semiconductor substrate 100 of the bottom of the second trenches 107b by performing a second STI ion implantation process. The second ion implantation regions IR2 prevent leakage current for punch between isolation structures. In the second STI ion implantation process, the ion incident angle is vertical to the semiconductor substrate 100, the ion implantation concentration is lower than the ion implantation concentration of the first STI ion implantation process, and the ion implantation energy is higher than the ion implantation energy of the first STI ion implantation process. As a result, the lower part of the inner wall of the trenches 107 where the second ion implantation region IR2 exists has an ion concentration that is lower than the upper part of the inner wall of the trenches 107 where the first ion implantation region IR1 exists. It is preferable that the second STI ion implantation process use boron as the ion for implantation.

Referring to FIG. 5, in order to reduce damage done by etching that occurs during etch process for forming isolation trench 107, A liner insulating layer 108 is formed over the entire structure including the isolation trench 107. Preferably, the liner insulating layer 108 is formed of an oxide film. An insulating layer 109 is formed on the entire structure including the liner insulating layer 108 so that isolation structure is formed by filling the isolation trench 107.

Thereafter, the insulating layer 109 for isolation structure and the liner insulating layer 108 are etched such that a silicon oxy-nitride layer 106 for a hard mask is exposed, and the exposed silicon oxy-nitride layer 106, an oxide layer for a hard mask 105, a nitride layer for a hard mask 104, and a buffer oxide layer 103 are removed, thereby forming a protruded isolation insulating layer 110 in the isolation trench 107. Thereafter, the upper part of the isolation structures 110 is etched such that the effective field height is adjusted. Here, the height of the upper part of the isolation structures 110 is preferably lower than the height of the upper part of the conductive layer for a floating gate 102.

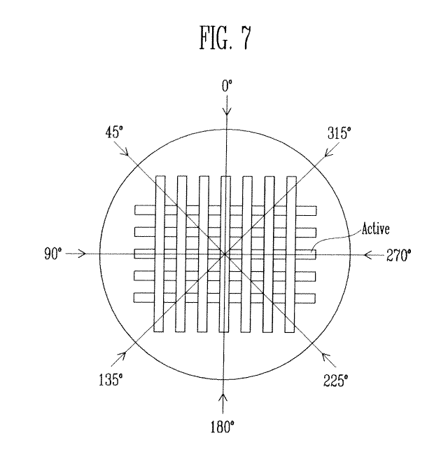

Referring to FIG. 6, the conductive layer for the floating gate 102 and the tunnel insulating layer 101 are etched in the direction of word lines by performing a gate pattern etch process.

Next, junction regions 111 are formed by an ion implantation process, an ion implantation process is performed in order to implant junction ions for forming a source and a drain within the semiconductor substrate 100. In a conventional ion implantation process using an incident angle which is vertical to the semiconductor substrate 100, a doping concentration at the junction region and gate edge portions is increased, but a concentration at the edge portion of the active region is lower than that the central portion of the active region.

To prevent this problem, during the ion implantation process, the incident angle is controlled to be 1° to 90° with respect to the semiconductor substrate 100.

FIG. 7 is a diagram showing the ion implantation directions of an ion implantation process during the ion implantation process of FIG. 5. The ion implantation process may be performed on a wafer in a number of directions (for example, eight directions; 0°, 45°, 90°, 135°, 180°, 225°, 270°, and 315°), not in both directions with respect to a wafer. Alternatively, the ion implantation process may be performed while the wafer is rotated so that the ion implantation process is performed in all directions.

According to an embodiment of the disclosure, the side portions of the active region of the semiconductor substrate are exposed by etching the predetermined thickness of the isolation structure as much as the junction region depth in a semiconductor device to be formed later during an isolation process, and an STI ion implantation process is performed on the exposed side portions of the active region. Accordingly, a cycling characteristic can be improved because an ion impurity concentration at the edge portion of the active region is maintained, and the central and edge portions of a subsequent junction region can be formed uniformly.

What is claimed is:

1. A method of manufacturing semiconductor devices, comprising:
forming a tunnel insulating layer, a conductive layer for a floating gate, and a hard mask layer over a semiconductor substrate;
forming a first trench in the semiconductor substrate by partially etching the hard mask layer, the conductive layer for the floating gate, the tunnel insulating layer, and the semiconductor substrate;
forming a first ion implantation region having a first impurity concentration into the semiconductor substrate of inner walls of the first trench by performing a first ion implantation process;
forming a second trench extending from the first trench by etching the semiconductor substrate of a bottom of the first trench; and
forming a second ion implantation region having a second impurity concentration lower than the first impurity concentration into the semiconductor substrate of inner walls of the second trench by performing a second ion implantation process,
wherein a depth of the first trench is shallower than that of a junction region.

2. The method of claim 1, further comprising:
forming a liner insulating layer over the entire structure including the first and the second trenches after the second ion implantation process;
forming an insulating layer over the liner insulating layer by filling the first and the second trenches; and
removing the hard mask film.

3. The method of claim 1, wherein the first ion implantation process is performed using boron or BF₂, and the second ion implantation process is performed using boron.

4. The method of claim 1, wherein a ion implantation energy of the second ion implantation process is higher than that of the first ion implantation process.

5. The method of claim 1, wherein the second ion implantation process is performed using an incident angle which is vertical to the semiconductor substrate.

6. The method of claim 1, further comprising:
forming the junction region by performing a source drain ion implantation process after exposing an active region of the semiconductor substrate by etching the conductive layer for the floating gate, tunnel insulating layer in a direction of a word line.

7. The method of claim 1, wherein the second ion implantation region is further formed in the semiconductor substrate of a bottom of the second trench during the second implantation process.

8. A method of manufacturing semiconductor devices, comprising:
forming a tunnel insulating layer and a conductive layer for a floating gate over a semiconductor substrate;
forming a first trench in the semiconductor substrate by partially etching the conductive layer for the floating gate, the tunnel insulating layer and the semiconductor substrate;
forming a first ion implantation region in the semiconductor substrate of inner walls of the first trench by performing a first ion implantation process;
forming a second trench extending from the first trench by etching the semiconductor substrate of a bottom of the first trench;
forming a second ion implantation region in the semiconductor substrate of inner walls of the second trench by performing a second ion implantation process;
forming an isolation structure by filling the first and the second trench with an insulating layer;
exposing an active region of the semiconductor substrate by etching the conductive layer for the floating gate and the tunnel insulating layer in a direction of a word line; and
forming a junction region in the semiconductor substrate of the exposed active region by performing a third ion implantation process,
wherein a depth of the first trench is shallower than the junction region.

9. The method of claim 8, wherein the first ion implantation process is performed using boron or BF₂, and the second ion implantation process is performed using boron.

10. The method of claim 8, wherein the second ion implantation region is further formed in the semiconductor substrate of a bottom of the second trench during the second ion implantation process.

11. The method of claim 8, wherein a ion implantation energy of the second ion implantation process is higher than that of the first ion implantation process.

12. The method of claim 8, wherein the second ion implantation process is performed using an incident angle which is vertical to the semiconductor substrate.

13. A semiconductor device, comprising:
an isolation structure having a first and a second trench formed in a semiconductor substrate; a first ion implantation region formed in the semiconductor substrate of inner walls of the first trench having a first impurity concentration; and
a second ion implantation region formed in the semiconductor substrate of inner walls of the second trench having a second impurity concentration which is lower than the first impurity concentration,
wherein a depth of the first trench is shallower than that of a junction region.

14. The device of claim 13, wherein the first trench is the upper part of the isolation structure and the second trench is lower part of the isolation structure which is extending from the first trench.

15. The device of claim 13, wherein the first ion implantation region maintains the ion concentration of an edge of an active region of the semiconductor substrate at a predetermined concentration or higher.

16. The device of claim 13, wherein the second ion implantation region prevents the leakage current for punch between the isolation structures.

17. The device of claim 13, wherein the second ion implantation region is further formed in the semiconductor substrate of a bottom of the trench.
